(19) United States
(12) Patent Application Publication
(10) Pub. No.: US 2003/0116279 A1
(43) Pub. Date: Jun. 26, 2003

(54) Apparatus for chemical vapor deposition

(75) Inventor: Kyung Sik Shim, Songnam-shi (KR)

Correspondence Address: Marger Johnson & McCollom, P.C., 1030 SW Morrison Street, Portland, OR, 97205, US

(73) Assignee: Jusung Engineering Co., Ltd., Kawagju-gun (KR)

(21) Appl. No.: 10/326,773

(22) Filed: Dec. 20, 2002

(30) Foreign Application Priority Data
Dec. 26, 2001 (KR) 2001-85121

(51) Int. Cl. C23F 1/00; C23C 16/00

(52) U.S. Cl. 156/345.33; 118/723 R; 156/345.1; 118/715

(57) ABSTRACT

Disclosed is an apparatus for a chemical vapor deposition, which comprises: a reaction chamber 10 having an upper inner wall and a lower inner wall, the lower inner wall being inwardly further protruded than the upper inner wall to form a stepped portion between the lower inner wall and the upper inner wall; a wafer supporting die 50 installed within the reaction chamber 10; a gas focus ring 70 installed in the upper inner wall; a purge gas supply hole 90 installed in a bottom face of the reaction chamber 10; a gas discharge hole 80 installed in an upper portion of the lower inner wall; and a pumping line 82 for connecting the gas discharge hole 80 with a vacuum pump. This invention can prevent the process gas from being deposited on a lower portion of the reaction chamber 10. If accumulation of the gas occurs around the gas discharge hole 80, a burning phenomenon appears around the gas discharge hole 80 due to the heat of a main heater installed inside the wafer supporting die 50. At this time, the accumulation of the gas can be minimized by installing the gas discharge hole 80 on the upper portion of the lower inner wall. Further, uniform deposition of a thin film can be achieved through an assembly of the gas focus ring 70, a quartz dome 20 and a belljar heater 40 with respect to a wider area than a conventional showerhead method.

### BACKGROUND OF THE INVENTION

1. Field of the Invention

The present invention relates to a CVD apparatus, and more particularly, to a CVD apparatus capable of preventing an undesired thin film deposited on a lower portion of a reaction chamber from acting as a particle source, and preventing a gas from being accumulated within the reaction chamber in a gas discharge operation.

2. Description of the Related Art

In a conventional chemical vapor deposition (CVD) apparatus, gas discharge holes are mostly installed in a lower portion of a reaction chamber. Accordingly, when gases that do not contribute to the deposition of a thin film are discharged through the gas discharge holes to an exterior, there is a problem that the gases are deposited on a lower portion of the reaction chamber and thus the deposited portion acts as a particle source.

In addition, a conventional low-pressure chemical vapor deposition (LPCVD) apparatus employs generally a method of supplying a gas into the reaction chamber through a showerhead. The method is adapted to deposit a uniform thin film on an entire wafer, and in some cases the method has an advantage that a plasma enhanced chemical vapor deposition (PECVD) process can be easily performed using the showerhead as a plasma electrode. However, since the showerhead must approach very near to the wafer so as to allow the gas to reach the entire wafer, the method has a disadvantage that a process is performed at a relatively high pressure of 300 torr or greater. Therefore, a characteristic of the LPCVD process may not be fully achieved and a step coverage or a loading effect may be degraded.

Further, since the conventional CVD process is performed employing a cold wall method in which the wafer is heated using only a heater mounted inside a wafer supporting die, the conventional CVD apparatus has a burden that the heater must be heated to a relatively high temperature.

### SUMMARY OF THE INVENTION

Therefore, the present invention has been devised to solve the above problems, and it is an object of the present invention to provide a CVD apparatus which does not allow gases that do not contribute to the deposition of a thin film to fall to a lower portion of a reaction chamber, thereby improving the injection method of a process gas and introducing an appropriate discharge method.

According to an embodiment of the present invention, there is provided an apparatus for a chemical vapor deposition. The apparatus includes: a reaction chamber having an upper inner wall and a lower inner wall, the lower inner wall being inwardly further protruded than the upper inner wall to form a stepped portion between the lower inner wall and the upper inner wall; a wafer supporting die installed within the reaction chamber; a gas focus ring installed in the upper inner wall, for injecting a process gas from a surrounding of the wafer supporting die to a center of an upper space of the wafer supporting die; a purge gas supply hole installed in a bottom face of the reaction chamber, for supplying a purge gas into an inside of the reaction chamber; a gas discharge hole installed in an upper portion of the lower inner wall, for discharging the process gas and the purge gas; and a pumping line for connecting the gas discharge hole with a vacuum pump.

### BRIEF DESCRIPTION OF THE DRAWINGS

The above objects and other advantages of the present invention will become more apparent by describing in detail preferred embodiments thereof with reference to the attached drawing in which:

FIG. 1 is a schematic view of a CVD apparatus in accordance with an embodiment of the present invention.

### DETAILED DESCRIPTION OF THE PREFERRED EMBODIMENTS

Now, preferred embodiments of the present invention will be described in detail with reference to the annexed drawings.

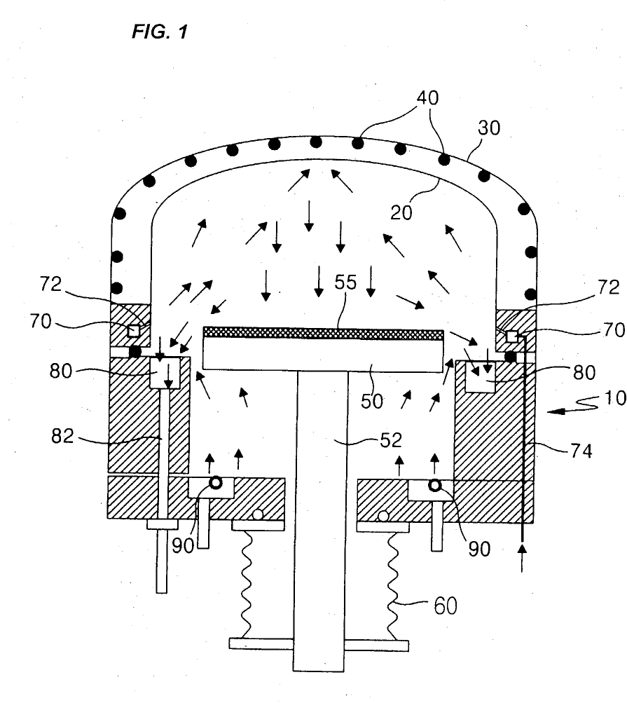

FIG. 1 is a schematic view of a chemical vapor deposition (CVD) apparatus in accordance with an embodiment of the present invention. Referring to FIG. 1, a reaction chamber 10 is a single wafer reaction chamber in which wafers are loaded one after another, and an upper portion of the reaction chamber 10 is made of a quartz dome 20. A belljar 30 is installed in an outer surface of the quartz dome 20 to cover the quartz dome 20 and a belljar heater 40 is installed in an inner surface of the belljar 30.

One wafer supporting die 50 is installed within the reaction chamber 10 and one wafer 55 is loaded on the wafer supporting die 50. A main heater (not shown) for heating the wafer to an appropriate temperature at which the CVD process can be performed is installed inside the wafer supporting die 50. The wafer supporting die 50 is supported by a supporting shaft 52 and the supporting shaft 52 is surrounded with bellows 60. Therefore, even when the supporting shaft 52 is moved upwardly and downwardly, the inside of the reaction chamber 10 is maintained in a tightly shut state from an exterior due to the bellows 60.

The reaction chamber 10 has an upper inner wall and a lower inner wall, and the lower inner wall is inwardly further protruded than the upper inner wall to form a stepped portion between the lower inner wall and the upper inner wall. The stepped portion is formed horizontally in a ring shape along the lower inner wall of the reaction chamber 10, and a top face of the lower inner wall is a flat plane. A gas focus ring 70 capable of injecting a process gas from a surrounding of the wafer supporting die 50 to a center of an upper space of the wafer supporting die 50 is installed in the upper inner wall of the reaction chamber 10. A plurality of injection nozzles 72 are installed in the gas focus ring 70. In addition, instead of the injection nozzles 72, a plurality of injection rings can be installed. A purge gas supply hole 90 for supplying a purge gas such as N₂ and Ar into the reaction chamber 10 is installed in a bottom face of the reaction chamber 10.

A gas discharge hole 80 for discharging the process gas and the purge gas is installed in an upper portion of the lower inner wall. The gas discharge hole 80 is extended along the top face of the lower inner wall to have a ring shape. The process gas and the purge gas introduced through the gas discharge hole 80 are discharged out of the reaction chamber 10 through a pumping line 82 coupled with a vacuum pump (not shown). The gas discharge hole 80 is installed in such a structure so as to easily discharge the gas out of the reaction chamber 10 without any accumulation of the gas.

If the process gas is introduced into the gas focus rings 70 through a gas supply line 74, the process gas is injected from the surrounding of the wafer supporting die 50 through the injection nozzles 72 to the center of the upper space of the wafer supporting die 50. The process gas injected to the center of the upper space of the wafer supporting die 50 is collided with the quartz dome 20 heated by the belljar heater 40, so that the process gas is pyrolyzed and wholly distributed on the upper space. Accordingly, even if the wafer is a large wafer, the chemical vapor deposition can be uniformly performed on an entire face of the wafer.

A remaining process gas unrelated to the chemical vapor deposition is discharged out of the reaction chamber 10 through the gas discharge hole 80. At this time, to prevent the process gas from going down to the lower portion of the reaction chamber 10, the purge gas is supplied through the purge gas supply hole 90 at an appropriate flow rate. Of course, it is also necessary to cause the purge gas not to go up to the upper portion of the reaction chamber 10 due to a pressure of the process gas.

Since the process gas cannot go down to a lower space of the wafer supporting die 50 by a supply of the purge gas, it is possible to prevent the thin film from being deposited on the lower portion of the reaction chamber 10. In addition, since the purge gas cannot also go up to an upper space of the wafer supporting die 50, the chemical vapor deposition process is not affected. Consequently, the purge gas does not affect uniformity and deposition rate of the thin film.

As described above, since the process gas cannot go down to the lower space of the reaction chamber 10 due to the pressure of the purge gas, it is possible to prevent the process gas from being deposited on the lower portion of the reaction chamber 10. Accordingly, particle occurrence sources can be minimized and a cleaning period of the CVD apparatus can be prolonged. At this time, since the purge gas cannot also go up to the upper space of the reaction chamber 10 due to the pressure of the process gas, the chemical vapor deposition process is not affected due to the purge gas.

If an accumulation of the gas occurs around the gas discharge hole 80, a burning phenomenon appears around the gas discharge hole 80 due to a heat of the main heater installed inside the wafer supporting die 50. At this time, as described above, the accumulation of the gas can be minimized by installing the gas discharge hole 80 in the upper portion of the lower inner wall.

Further, according to the present invention, a uniform thin film deposition can be achieved through an assembly of the gas focus ring 70, the quartz dome 20 and the belljar heater 40 with respect to a wider area than a conventional showerhead method.

While the present invention has been described in detail, it should be understood that various changes, substitutions and alterations could be made hereto without departing from the spirit and scope of the invention as defined by the appended claims.

What is claimed is:

1. An apparatus for a chemical vapor deposition comprising:
a reaction chamber having an upper inner wall and a lower inner wall, the lower inner wall being inwardly further protruded than the upper inner wall to form a stepped portion between the lower inner wall and the upper inner wall;
a wafer supporting die installed within the reaction chamber;
a gas focus ring installed in the upper inner wall, for injecting a process gas from a surrounding of the wafer supporting die to a center of an upper space of the wafer supporting die;
a purge gas supply hole installed in a bottom face of the reaction chamber, for supplying a purge gas into an inside of the reaction chamber;
a gas discharge hole installed in an upper portion of the lower inner wall, for discharging the process gas and the purge gas; and
a pumping line for connecting the gas discharge hole with a vacuum pump.

2. The apparatus of claim 1, wherein the stepped portion is formed horizontally in a ring shape along the lower inner wall of the reaction chamber, a top face of the lower inner wall being a flat plane, the gas discharge hole being extended along the top face of the lower inner wall to have a ring shape.

3. The apparatus of claim 1, wherein the reaction chamber comprises an upper portion made of a quartz dome.

4. The apparatus of claim 3, further comprising a belljar covering the quartz dome on an outer surface of the quartz dome, and a belljar heater covering the quartz dome on an inner surface of the belljar.

5. The apparatus of claim 1, wherein the reaction chamber is a single wafer reaction chamber in which the wafer supporting die is one and only one sheet of wafer is loaded.

6. The apparatus of claim 1, further comprising a heater installed inside the wafer supporting die.
